(19) United States
(12) Patent Application Publication
(10) Pub. No.: US 2008/0079135 A1
(43) Pub. Date: Apr. 3, 2008

(54) Package assembly pinout with superior crosstalk and timing performance

(76) Inventor: Jitesh Shah, Fremont, CA (US)

Correspondence Address: The Law Office of Steven G. Roeder, 5560 Chelsea Avenue, La Jolla, CA, 92037, US

(21) Appl. No.: 11/540,068

(22) Filed: Sep. 29, 2006

(51) Int. Cl. H01L 23/52

(52) U.S. Cl. 257/691

(57) ABSTRACT

An integrated circuit package (212) for electrically connecting an integrated circuit (216) to a substrate (214) includes a package assembly (218) having an outer periphery (324) and a pinout (220) that includes a first pin array (334), a second pin array (336) and a third pin array (338). The first pin array (334) includes a plurality of consecutively positioned signal pins (322S). The second pin array (336) includes a plurality of power pins (322P) and ground pins (322G) interspersed with one another. The second pin array (336) is positioned nearer the outer periphery (324) than the first pin array (334). The third pin array (338) includes a plurality of consecutively positioned signal pins (322S) and is positioned nearer the outer periphery (324) than the second pin array (336).

### BACKGROUND

It is well known that integrated circuits (also referred to as “chips”) are often coupled to substrates such as a printed circuit board via a package assembly (also sometimes referred to herein as a “package”). In certain instances, the package assembly includes a pinout that bonds to the substrate. The pinout can also be referred to as a ball grid array (“BGA”). FIG. 1 illustrates a simplified bottom view diagram of a conventional, prior art integrated circuit package 12P including a package assembly 18P. These conventional package assemblies 18P include a pinout 20P having a plurality of pins including I/O power pins 22PP (illustrated as “P”) and ground pins 22GP (illustrated as “G”) which are located towards the center of the package assembly 18P, with signal pins 22SP (illustrated as “S”) positioned at an outer periphery 24P of the package assembly 18P, as illustrated in FIG. 1. The pinout 20P can also include a core power supply pin array 26P positioned at or near the center of the package assembly 18P. The core power supply pin array 26P supplies power to and is in direct electrical communication with the integrated circuit.

In the pinout 20P illustrated in FIG. 1, each power pin 22PP provides power to a plurality of signal pins 22SP. One ground pin 22GP is associated with each power pin 22PP. The combination of one power pin 22PP, one ground pin GP and one signal pin SP results in a signal-return loop 28P having a magnetic field (not shown). As illustrated in FIG. 1, the prior art pinout 20P utilizes multiple consecutively positioned signal pins 22SP for each power pin 22PP/ground pin GP pair.

In typical package assemblies 18P that include ball grid arrays (e.g., in flip chip packages, as one non-exclusive example), a significant portion of the inductive coupling occurs between vertical vias and solder balls of multiple signal-return loops 28P overlapping with each other. The signal pins 22SP in the outermost array near the outer periphery 24P of the package assembly 18P overlap with the most number of signal-return loops 28P. Hence, the observed crosstalk on these outermost signal pins 22SP is the highest and it gradually decreases for the signal pins 22SP positioned more inwardly toward the center of the package assembly 18P. The innermost pins signal pins 22SP have the lowest magnetic field coupling and hence the lowest crosstalk. Increased crosstalk also severely affects the timing margins for the package assembly 18P causing longer time delays between the inner and the outer signal pins 22SP.

### SUMMARY

The present invention includes embodiments directed toward an integrated circuit package for electrically connecting an integrated circuit to a substrate. The substrate can be a printed circuit board, for example. In some embodiments, the integrated circuit package includes a package assembly having an outer periphery and a pinout that includes a first pin array, a second pin array and a third pin array. The first pin array includes a plurality of consecutively positioned signal pins. The second pin array includes a plurality of power pins and ground pins interspersed with one another. The second pin array is positioned nearer the outer periphery than the first pin array. The third pin array includes a plurality of consecutively positioned signal pins and is positioned nearer the outer periphery than the second pin array. In this embodiment, the second pin array is positioned substantially between the first pin array and the third pin array.

In one embodiment, the pinout includes a fourth pin array positioned further from the outer periphery than the first pin array. In this embodiment, the fourth pin array includes a plurality of power pins and ground pins interspersed with one another. Further, the pinout can include a fifth pin array positioned substantially between the fourth pin array and the first pin array. In this embodiment, the fifth pin array includes a plurality of consecutively positioned signal pins. In certain embodiments, one of the first, second and third arrays includes at least three substantially collinear pins. Alternatively, each of the first second and third arrays includes at least three substantially collinear pins.

In another embodiment, the pins of at least one of the first, second and third arrays are positioned in a substantially rectangular configuration. Further, at least a portion of each of the first, second and third arrays can be substantially parallel to one another.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified bottom view diagram of a prior art integrated circuit package including a pinout;

FIG. 2 is a simplified side view of an integrated circuit assembly having features of the present invention;

FIG. 3 is a simplified bottom view diagram of an integrated circuit package including one embodiment a package assembly having features of the present invention;

FIG. 4 is a simplified bottom view diagram of the integrated circuit package including another embodiment the package assembly;

FIG. 5 is a simplified bottom view diagram of the integrated circuit package including yet another embodiment the package assembly; and

FIG. 6 is a simplified bottom view diagram of the integrated circuit package including still another embodiment the package assembly.

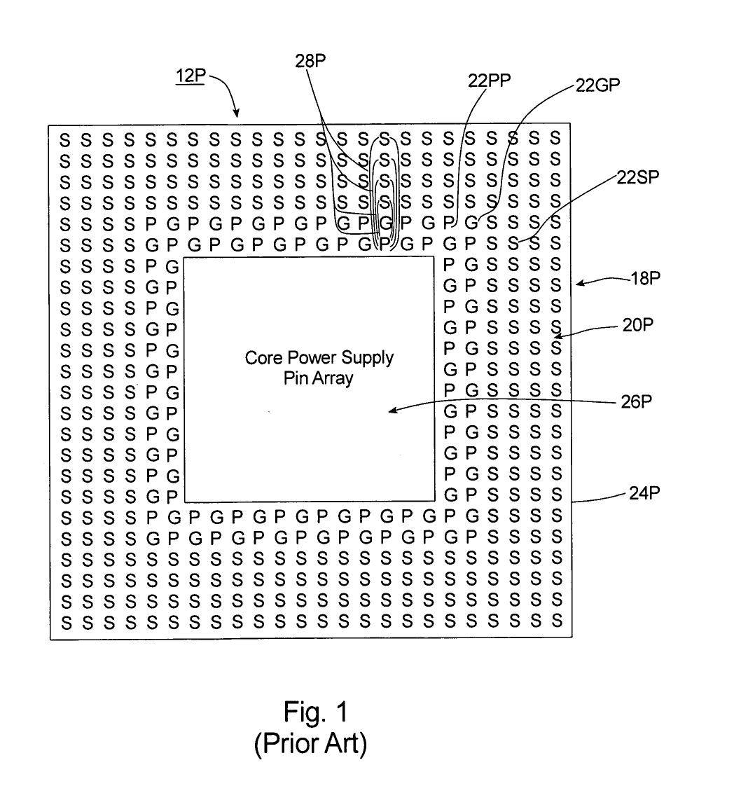

### DESCRIPTION

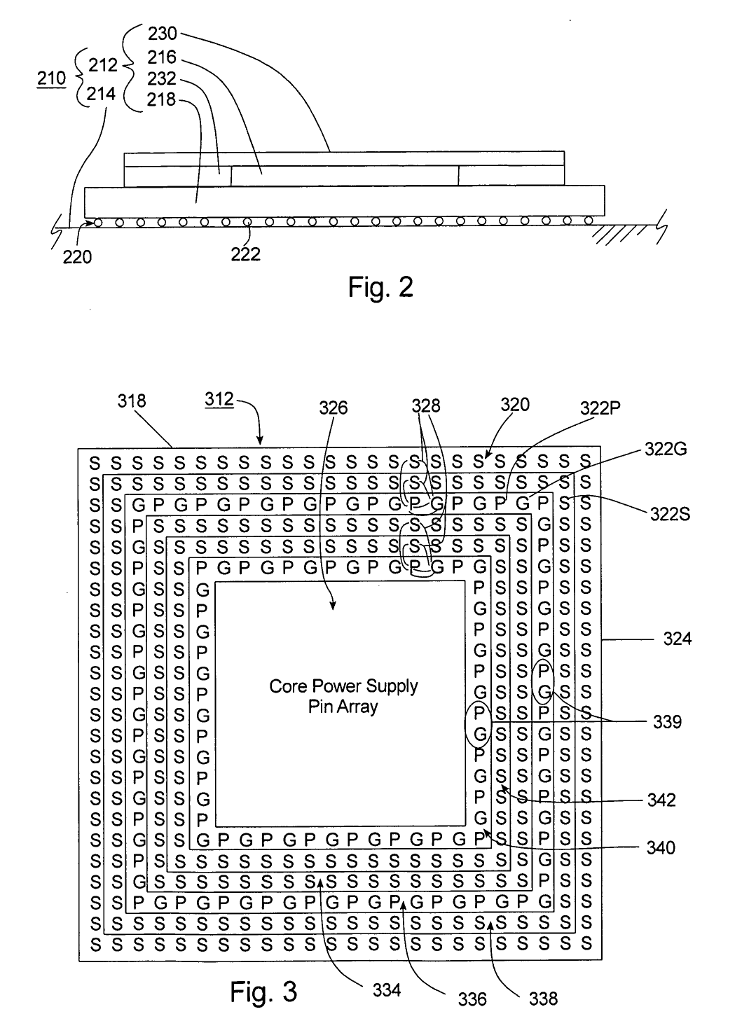

FIG. 2 is a simplified side view of an integrated circuit assembly 210 including an integrated circuit package 212 and an adjacent substrate 214. In this embodiment, the integrated circuit package 212 includes an integrated circuit 216, a package assembly 218, a heat spreader 230 and one or more insulators 232. The integrated circuit 216 is in electrical communication with the package assembly 218. In certain embodiments, the integrated circuit 216 is directly or indirectly secured to the package assembly 218.

The heat spreader 230 is positioned near the integrated circuit 216 and can spread, distribute or otherwise disperse heat to protect the integrated circuit 216 and/or the package assembly 218 from being subjected to excessive temperatures, for example. In one embodiment, the heat spreader 230 can be formed from a material having a relatively high thermal conductivity. For example, the heat spreader 230 can be formed from a metallic material, or any other suitable material.

The one or more insulators 232 can be positioned between the heat spreader 230 and the package assembly 218. The insulator 232 can provide a protective barrier for an otherwise exposed edge of the integrated circuit 216. Additionally, the insulator 232 and can fill the gap that would otherwise exist between the heat spreader 230 and the package assembly 218 to provide structural stability to the integrated circuit package 212. In one embodiment, the insulator 232 can be formed from a substantially non-conductive material, such as a dielectric material or another suitable material.

In the embodiment illustrated in FIG. 2, the package assembly 218 includes a pinout 220 than can include a ball grid array (BGA), as one non-exclusive example. The pinout 220 can electrically and/or mechanically couple the package assembly 218 to the substrate 214. The pinout 220 can include a plurality of pins 222 that are directly or indirectly secured to the substrate 214. In one non-exclusive embodiment, the pins are solder balls. In various embodiments, the pins 222 can include ground pins, power pins and/or signal pins. In the embodiments provided herein, different types of pins 222 are strategically arranged in various patterns and arrays to reduce crosstalk and/or to improve signal timing margins, as explained in greater detail below.

The substrate 214 supports the integrated circuit package 212. In certain embodiments, the substrate 214 is a printed circuit board (PCB). In alternative embodiments, the substrate 214 can be another suitable type of supporting structure known to those skilled in the art.

FIG. 3 is a simplified bottom view diagram of the integrated circuit package 312 including a first embodiment of a package assembly 318 having a pinout 320. In this embodiment, the integrated circuit package 312 includes a core power supply pin array 326, a plurality of ground pins 322G (indicated with a “G”), a plurality of power pins 322P (indicated with a “P”), and a plurality of signal pins 322S (indicated with a “S”). In the embodiment illustrated in FIG. 3, an array of power pins 322P and ground pins 322G are positioned directly between and adjacent to two arrays or rows of signal pins 322S.

In certain embodiments including the embodiment illustrated in FIG. 3, the pinout 320 can include a first pin array 334, a second pin array 336 and a third pin array 338. As used herein, the term “pin array” means a non-random pattern of one specific type or a plurality of specific types of pins. For example, one pin array can include only signal pins 322S. Another pin array can include both power pins 322P and ground pins 322G that are alternately interspersed with one another. Thus, although the types of pin arrays are to be positioned relative to one another consistent with the teachings herein, a pattern of specific types of pins within the pinout 320 determines the presence of a pin array.

Further, the pins within a given pin array can have the characteristic of being substantially equidistant from a particular structure, such as an outer periphery 324 of the package assembly 318, or from the core power supply pin array 326, as non-exclusive examples. Alternatively, the pins of a given pin array can have varied distances from certain structures and need not be equidistant from any one particular structure. Moreover, although rectangles are illustrated in certain figures, these are provided to delineate the pin arrays only, and are not actual structures of the package assemblies herein.

Additionally, the use of the terms “first”, “second”, “third”, etc., in the context of pin arrays, are for the sake of convenience and ease in understanding the invention only and are not intended to be limiting in any manner. In other words, any of the pin arrays can be the “first pin array”, the “second pin array”, or the “third pin array”, etc.

In the embodiment illustrated in FIG. 3, the first pin array 334 is positioned near the core power supply array pin array 326. The second pin array 336 is generally positioned further from the core power supply pin array 326 than the first pin array 334. Stated another way, the second pin array 336 is positioned nearer outer periphery 324 than the first pin array 334. The third pin array 338 is positioned nearer the outer periphery 324 than the first pin array 334 and the second pin array 336. Further, in this embodiment, the second pin array 336 is positioned substantially directly between the first pin array 334 and the third pin array 338.

In the embodiment illustrated in FIG. 3, the first pin array 334, the second pin array 336 and/or the third pin array 338 can each have pins in a substantially rectangular configuration. Alternatively, one or more of the pin arrays 334, 336, 338, can have a different configuration such as elliptical, circular, or any other suitable configuration.

Still alternatively, one or more of the pin arrays 334, 336, 338 can include a subset of the pin arrays identified in FIG. 3. For example, rather than the pin array extending completely around or encircling the core power supply pin array 326, one or more of the pin arrays 334, 336, 338 can extend only partially around or along the core power supply pin array 326. Stated another way, one or more of the pin arrays can be a subset of the respective pin arrays 334, 336, 338 illustrated in FIG. 3, such as a row of three substantially collinear pins, as one non-exclusive example. Alternatively, one or more of the pin arrays 334, 336, 338 can include four or any other suitable number of substantially collinear pins. Still alternatively, each of the pins in the pin array 334, 336, 338 can be substantially equidistant from the outer periphery 324 of the package assembly 318 from one another, whether or not the pins are substantially collinear. In certain embodiments, one or more of the pin arrays can consist of two or more pins that are substantially equidistant from the outer periphery 324 of the package assembly 318 or from the core power supply pin array 326, as non-exclusive examples.

In the embodiment illustrated in FIG. 3, the first pin array 334 is illustrated immediately adjacent to the second pin array 336. Alternatively, the first pin array 334 need not be positioned immediately adjacent to the second pin array 336. For example, another pin array can be positioned between the first pin array 334 and the second pin array 336.

In FIG. 3, the first pin array 334 includes signal pins 322S, consecutively positioned relative to one another. The second pin array 336 includes power pins 322P interspersed with ground pins 322G so that the second pin array 336 includes a plurality of power/ground pairs 339 (representative power/ground pairs 339 are identified by an oval around one ground pin 322G and one power pin 322P). The third pin array 338 includes consecutively positioned signal pins 322S. Stated another way, a pin array of power pins 322P and ground pins 322G is positioned directly between two pin arrays of signal pins 322S.

Additionally, in this and other embodiments, the pinout 320 can include a fourth pin array 340 that is positioned substantially between the core power supply pin array 326 and the first pin array 334. Stated another way, the fourth pin array 340 is positioned further from the outer periphery 324 than the first pin array 334. In the embodiment illustrated in FIG. 3, the fourth pin array 340 includes power pins 322P interspersed with ground pins 322G in a manner somewhat similar to that of the second pin array 336.

With the design provided in the embodiment illustrated in FIG. 3, the second pin array 336 (power and ground pins) provides power to the third pin array 338 (signal pins). Each signal pin 322S in the third pin array 338 is associated with one power pin 322P and one ground pin 322G in the second pin array 336 to form a signal-return loop 328 during processing. Somewhat similarly, each signal pin 322S in the first pin array 334 is associated with one power pin 322P and one ground pin 322G in the fourth pin array 340 to form another signal-return loop 328 during processing. Because these signal-return loops 328 are separated from one another, crosstalk between these signal-return loops 328 is reduced.

Further, as illustrated in FIG. 3, the disparity in the length of each signal-return loop 328, e.g., the distance that the signal must travel, is reduced because the length of even the longest signal-return loops 328 is reduced. As a result, time delays for signal pins 322S that are furthest from the power/ground pairs 339 are decreased since these signal pins 322S are still relatively close to the power/ground pairs 339.

In the embodiment illustrated in FIG. 3, the pinout 320 can include a fifth pin array 342 that is positioned between the first pin array 334 and the fourth pin array 340. In one embodiment, the fifth pin array 342 includes a plurality of consecutively positioned signal pins 322S.

It is recognized that the number of pin arrays in the pinout can vary depending upon the design requirements of the integrated circuit assembly 210 and the integrated circuit package 312. For example, pinouts having greater number of pins may have a greater number of pin arrays. The embodiments provided herein are merely illustrative of various non-exclusive examples of the pinout 320. Further, the number of pins in a given pin array can vary.

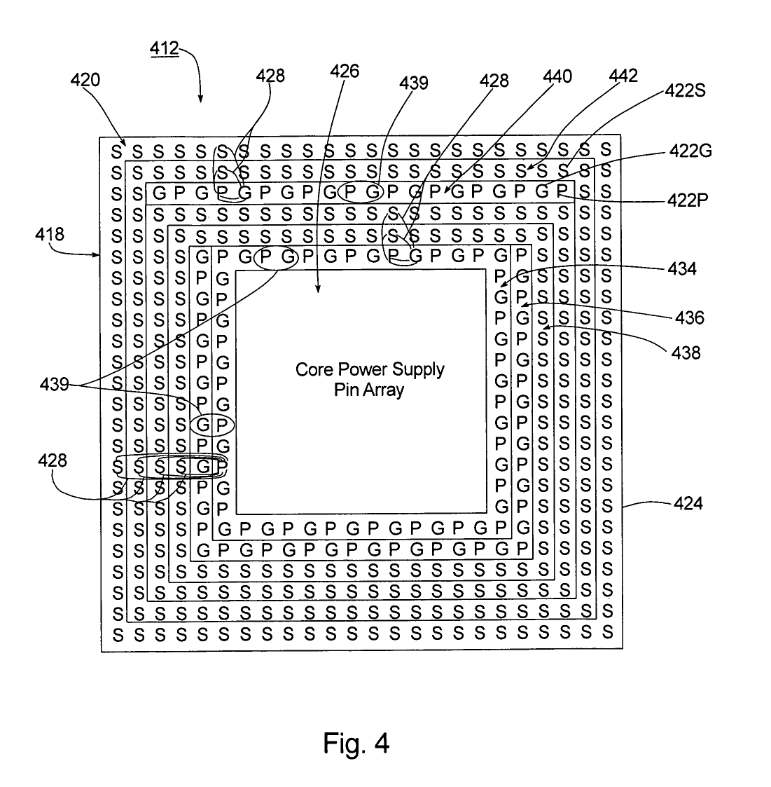

FIG. 4 illustrates a bottom view of an integrated circuit package 412 including a second embodiment of a package assembly 418 having a pinout 420. In this embodiment, the pinout 420 includes a core power supply pin array 426, a first pin array 434, a second pin array 436, a third pin array 438, a fourth pin array 440 and a fifth pin array 442. In this embodiment, the first pin array 434 substantially encircles the core power supply pin array 426 and includes power pins 422P interspersed with ground pins 422G so that the first pin array 434 includes a plurality of power/ground pairs 439 (representative power/ground pairs 439 are identified by an oval around one ground pin 422G and one power pin 422P).

The second pin array 436 does not completely encircle the core power supply pin array 426, but only extends around the core power supply pin array 426 on three of the four sides of the core power supply pin array 426, somewhat in the shape of a “U”. The second pin array 436 also includes power pins 422P interspersed with ground pins 422G. In this embodiment, each power pin 422P in the second pin array 436 combines with one ground pin 422G in the first pin array 434 to form a power/ground pair 439. Somewhat similarly, each ground pin 422G in the second pin array 436 combines with one power pin 422P in the first pin array 434 to form a power/ground pair 439. On one side of the first pin array 434 (shown as the uppermost side in FIG. 4) that is not adjacent to the second pin array 436, adjacent power pins 422P and ground pins 422G within the first pin array 434 form power/ground pairs 439.

In this embodiment, the third pin array 438 substantially encircles the core power supply pin array 426 and includes consecutively positioned signal pins 422S.

The fourth pin array 440 includes a substantially linear row of a plurality of power pins 422P interspersed with ground pins 422G so that the fourth pin array 434 includes a plurality of power/ground pairs 439.

The fifth pin array 442 substantially encircles the core power supply pin array 426 and includes consecutively positioned signal pins 422S that are substantially equidistant from an outer periphery 424 of the package assembly 418. In this embodiment, the fifth pin array 442 is nearer the outer periphery 424 than the fourth pin array 440. As illustrated in FIG. 4, some of the signal pins 422S of the fifth pin array 442 form signal-return loops 428 with the power/ground pairs 439 of the fourth pin array 440, and some of the signal pins 422S of the fifth pin array 442 form signal-return loops 428 with the second pin array 436.

In the embodiment illustrated in FIG. 4, a portion of pinout 420 includes power/ground pairs 439 that each forms signal-return 428 loops with only two signal pins 422S. The remainder of the power/ground pairs 439 each form signal-return loops 428 with greater than two signal pins 422S. This configuration may be beneficial depending upon the design requirements of the integrated circuit assembly 210 and/or the integrated circuit package 412.

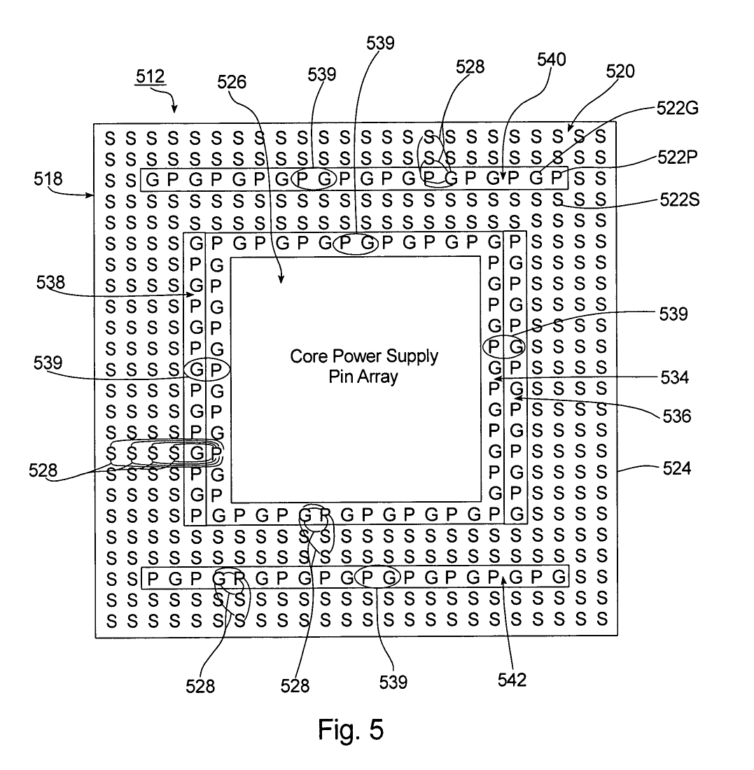

FIG. 5 illustrates a bottom view of an integrated circuit package 512 including a third embodiment of a package assembly 518 having a pinout 520. In this embodiment, the pinout 520 includes a core power supply pin array 526, a first pin array 534, a second pin array 536, a third pin array 538, a fourth pin array 540, a fifth pin array 542 and a sixth pin array 544. The first pin array 534 substantially encircles the core power supply pin array 526 and includes power pins 522P interspersed with ground pins 522G so that the first pin array 534 includes a plurality of power/ground pairs 539 (representative power/ground pairs 539 are identified by an oval around one ground pin 522G and one power pin 522P within the first pin array 534). The power/ground pairs 539 that are solely comprised of pins within the first pin array 534 are positioned along two sides of the first pin array 534 (the uppermost and the lowermost sides in FIG. 5).

The second pin array 536 includes a substantially linear row of power pins 522P interspersed with ground pins 522G. In this embodiment, each power pin 522P in the second pin array 536 combines with one ground pin 522G on an adjacent side of the first pin array 534 to form a power/ground pair 539. Somewhat similarly, each ground pin 522G in the second pin array 536 combines with one power pin 522P on an adjacent side of the first pin array 534 to form a power/ground pair 539. In the embodiment illustrated in FIG. 5, the second pin array 536 is substantially positioned near only one side of the core power supply pin array 526 (the right side in FIG. 5) and is positioned nearer the outer periphery 524 than the first pin array 534.

The third pin array 538 includes a substantially linear row of power pins 522P interspersed with ground pins 522G. In this embodiment, each power pin 522P in the third pin array 538 combines with one ground pin 522G on an adjacent side of the first pin array 534 to form a power/ground pair 539. Somewhat similarly, each ground pin 522G in the third pin array 538 combines with one power pin 522P on an adjacent side of the first pin array 534 to form a power/ground pair 539. In the embodiment illustrated in FIG. 5, the third pin array 538 is positioned near only one side of the core power supply pin array 526 (the left side in FIG. 5), and is positioned nearer the outer periphery 524 than the first pin array 534.

In this embodiment, the fourth pin array 540 includes a substantially linear row of a plurality of power pins 522P interspersed with ground pins 522G so that the fourth pin array 534 includes a plurality of power/ground pairs 539. Somewhat similarly, the fifth pin array 542 includes a substantially linear row of a plurality of power pins 522P interspersed with ground pins 522G so that the fourth pin array 534 includes a plurality of power/ground pairs 539. The fourth pin array 540 and the fifth pin array 542 are each positioned nearer the outer periphery 524 than the first pin array 534, the second pin array 536 and the third pin array 538.

The sixth pin array 544 substantially encircles the core power supply pin array 526 and includes consecutively positioned signal pins 522S that are substantially equidistant from an outer periphery 524 of the package assembly 518. In this embodiment, the sixth pin array 544 is nearer the outer periphery 524 than the fourth pin array 540 and the fifth pin array 542. As illustrated in FIG. 5, some of the signal pins 522S of the sixth pin array 544 form signal-return loops 528 with the power/ground pairs 539 of the fourth pin array 540, the fifth pin array 542 and the second pin array 536.

In the embodiment illustrated in FIG. 5, a portion of pinout 520 includes power/ground pairs 539 that each forms signal-return 528 loops with only two signal pins 522S. The remainder of the power/ground pairs 539 each form signal-return loops 528 with greater than two signal pins 522S. This configuration may be beneficial depending upon the design requirements of the integrated circuit assembly 210 and/or the integrated circuit package 512.

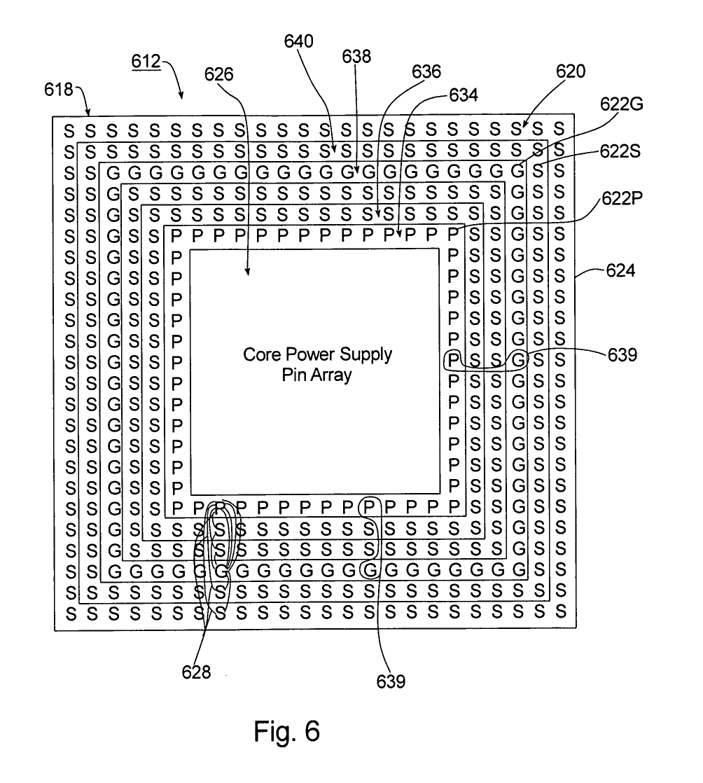

FIG. 6 illustrates a bottom view of an integrated circuit package 612 including a fourth embodiment of a package assembly 618 having a pinout 620. In this embodiment, the pinout 620 includes a core power supply pin array 626, a first pin array 634, a second pin array 636, a third pin array 638 and a fourth pin array 640. The first pin array 634 can substantially encircle the core power supply pin array 626 and includes a plurality of consecutively positioned power pins 622P.

The second pin array 636 substantially encircles the core power supply pin array 626 and includes a plurality of consecutively positioned signal pins 622S that are substantially equidistant from an outer periphery 624 of the package assembly 618. In this embodiment, the second pin array 636 is nearer the outer periphery 624 than the first pin array 634.

The third pin array 638 can substantially encircle the core power supply pin array 626, and includes a plurality of consecutively positioned ground pins 622G. In this embodiment, the third pin array 638 is nearer the outer periphery 624 than the second pin array 636. Thus, in this embodiment, the pinout 620 includes a plurality of power/ground pairs 639 which each has a power pin 622P and a ground pin 622G that are separated by one or more signal pins 622S, as illustrated in FIG. 6.

The fourth pin array 640 substantially encircles the core power supply pin array 626 and includes a plurality of consecutively positioned signal pins 622S that are substantially equidistant from an outer periphery 624 of the package assembly 618. In this embodiment, the fourth pin array 640 is nearer the outer periphery 624 than the third pin array 638.

As illustrated in FIG. 6, the signal pins 622S of each of the second pin array 636 and the fourth pin array 640 form signal-return loops 628 with the power/ground pairs 639 formed by the first pin array 634 and the third pin array 638.

While the particular integrated circuit assembly 210 including the embodiments of pinouts 320, 420, 520 as herein shown and disclosed in detail are fully capable of obtaining the objects and providing the advantages herein before stated, it is to be understood that they are merely illustrative of one or more embodiments and that no limitations are intended to the details of construction or design herein shown other than as described in the appended claims.

What is claimed is:

1. An integrated circuit package for electrically connecting an integrated circuit to a substrate, the integrated circuit package comprising:
a package assembly including an outer periphery and a pinout, the pinout having (i) a first pin array including a plurality of consecutively positioned signal pins, (ii) a second pin array positioned nearer the outer periphery than the first pin array, the second pin array including a plurality of at least one of power pins and ground pins, and (iii) a third pin array positioned nearer the outer periphery than the second pin array, the third pin array including a plurality of consecutively positioned signal pins;
wherein the second pin array is positioned substantially between the first pin array and the third pin array.

2. The integrated circuit package of claim 1 wherein the pinout includes a fourth pin array positioned further from the outer periphery than the first pin array, the fourth pin array including a plurality of at least one of power pins and ground pins.

3. The integrated circuit package of claim 2 wherein the fourth pin array includes a plurality of ground pins and power pins alternatingly interspersed with one another.

4. The integrated circuit package of claim 2 wherein the pinout includes a fifth pin array positioned substantially between the fourth pin array and the first pin array, the fifth pin array including a plurality of consecutively positioned signal pins.

5. The integrated circuit package of claim 1 wherein one of the first, second and third arrays includes at least three substantially collinear pins.

6. The integrated circuit package of claim 1 wherein each of the first second and third arrays includes at least three substantially collinear pins.

7. The integrated circuit package of claim 1 wherein the pins of at least one of the first, second and third arrays are positioned in a substantially rectangular configuration.

8. The integrated circuit package of claim 1 wherein at least a portion of each of the first, second and third arrays are substantially parallel to one another.

9. The integrated circuit package of claim 1 wherein the pins of one of the pin arrays are substantially equidistant from the outer periphery of the package assembly.

10. The integrated circuit package of claim 1 wherein the pins of the first pin array are substantially equidistant from the outer periphery of the package assembly, the pins of the second pin array are substantially equidistant from the outer periphery of the package assembly, and the pins of the third pin array are substantially equidistant from the outer periphery of the package assembly.

11. The integrated circuit package of claim 1 wherein the first pin array includes a plurality of ground pins and power pins alternatingly interspersed with one another.

12. An integrated circuit package for electrically connecting an integrated circuit to a substrate, the integrated circuit package comprising:
a package assembly including an outer periphery and a pinout, the pinout including (i) a first pin array including a plurality of power pins and ground pins interspersed with one another, (ii) a second pin array nearer the outer periphery than the first pin array, the second pin array including a plurality of consecutively positioned signal pins, and (iii) a third pin array positioned nearer the outer periphery than the second pin array, the third pin array including a plurality of power pins and ground pins interspersed with one another;
wherein the second pin array is positioned substantially between the first pin array and the third pin array.

13. The integrated circuit package of claim 12 wherein the pinout includes a fourth pin array positioned nearer the outer periphery than the third pin array, the fourth pin array including a plurality of consecutively positioned signal pins.

14. The integrated circuit package of claim 12 wherein one of the first, second and third arrays includes at least three substantially collinear pins.

15. The integrated circuit package of claim 12 wherein each of the first second and third arrays includes at least three substantially collinear pins.

16. The integrated circuit package of claim 12 wherein the pins of at least one of the first, second and third arrays are positioned in a substantially rectangular configuration.

17. The integrated circuit package of claim 12 wherein the pins of each of the first, second and third arrays are positioned in a substantially rectangular configuration.

18. The integrated circuit package of claim 12 wherein at least a portion of each of the first, second and third arrays are substantially parallel to one another.

19. The integrated circuit package of claim 12 wherein the substrate is a printed circuit board.

20. The integrated circuit package of claim 12 wherein the pins of one of the pin arrays are substantially equidistant from the outer periphery of the package assembly.

21. The integrated circuit package of claim 12 wherein the pins of the first pin array are substantially equidistant from the outer periphery of the package assembly, the pins of the second pin array are substantially equidistant from the outer periphery of the package assembly, and the pins of the third pin array are substantially equidistant from the outer periphery of the package assembly.

22. An integrated circuit package for electrically connecting an integrated circuit to a substrate, the integrated circuit package comprising:
a pinout including (i) a core power supply pin array, (ii) a first pin array including a plurality of consecutively positioned signal pins, (iii) a second pin array positioned further from the core power supply pin array than the first pin array, the second pin array including a plurality of power pins and ground pins adjacently interspersed with one another, and (iv) a third pin array positioned further from the core power supply pin array than the second pin array, the third pin array including a plurality of consecutively positioned signal pins.

23. The integrated circuit package of claim 22 wherein the pinout includes a fourth pin array positioned substantially between the first pin array and the core power supply pin array, the fourth pin array including a plurality of power pins and ground pins interspersed with one another.

24. The integrated circuit package of claim 23 wherein the pinout includes a fifth pin array positioned substantially between the fourth pin array and the first pin array, the fifth pin array including a plurality of consecutively positioned signal pins.

25. The integrated circuit package of claim 22 wherein one of the first, second and third arrays includes at least three substantially collinear pins.

26. The integrated circuit package of claim 22 wherein each of the first second and third arrays includes at least three substantially collinear pins.

27. The integrated circuit package of claim 22 wherein the pins of at least one of the first, second and third arrays are positioned in a substantially rectangular configuration.

28. The integrated circuit package of claim 22 wherein the pins of each of the first, second and third arrays are positioned in a substantially rectangular configuration.

29. The integrated circuit package of claim 22 wherein at least a portion of each of the first, second and third arrays are substantially parallel to one another.

30. The integrated circuit package of claim 22 wherein the substrate is a printed circuit board.

31. The integrated circuit package of claim 22 wherein the pins of one of the pin arrays are substantially equidistant from the outer periphery of the package assembly.

32. The integrated circuit package of claim 22 wherein the pins of the first pin array are substantially equidistant from the outer periphery of the package assembly, the pins of the second pin array are substantially equidistant from the outer periphery of the package assembly, and the pins of the third pin array are substantially equidistant from the outer periphery of the package assembly.
